(19) United States
(12) Patent Application Publication
(10) Pub. No.: US 2025/0221168 A1
(43) Pub. Date: Jul. 3, 2025

(54) DISPLAY APPARATUS WITH REDUCED OR NO DARK DOTS

(71) Applicant: LG Display Co., Ltd., Seoul (KR)

(72) Inventor: Joon-Suk LEE, Paju-si (KR)

(73) Assignee: LG Display Co., Ltd., Seoul (KR)

(21) Appl. No.: 19/003,708

(22) Filed: Dec. 27, 2024

(30) Foreign Application Priority Data
Dec. 29, 2023 (KR) 10-2023-0196869

(51) Int. Cl. H10K 59/121; H10K 59/122; H10K 59/127; H10K 59/38; H10K 59/80

(52) U.S. Cl. CPC H10K 59/1213; H10K 59/122; H10K 59/1275; H10K 59/38; H10K 59/8792

(57) ABSTRACT

A display apparatus according to the present disclosure may include a first substrate and a second substrate including a plurality of sub-pixels; a transistor disposed in a sub-pixel among the plurality of sub-pixels of the first substrate; a bank layer disposed between the plurality of sub-pixels; a light emitting device in the sub-pixel; an overcoat layer disposed in the second substrate; a filler disposed between the first substrate and the second substrate; and a groove formed in at least one of the overcoat layer and the bank layer in the sub-pixel.

### CROSS-REFERENCE TO RELATED APPLICATION

This application claims priority to Korean Patent Application No. 10-2023-0196869, filed in the Republic of Korea on Dec. 29, 2023, the entire contents of which are hereby expressly incorporated by reference into the present application.

### BACKGROUND

### Technical Field

The present disclosure relates to a display apparatus, including a display apparatus capable of preventing poor image quality caused by an uneven thickness of a filler.

### Description of the Related Art

As information technology develops, various types of small and thin display apparatus such as a Liquid Crystal Display Device, an Organic Light Emitting Display Device, a Plasma Display Device, a Micro LED Display Device, etc., are proposed. These display apparatuses are applied to various electronic devices such as smart phones and tablet PCs.

In this display apparatus, dark spots or stains appear on the screen for various reasons, which are major causes of defects in display apparatus.

### SUMMARY

An object of the present disclosure is to provide a display apparatus capable of prevent or reduce defects caused by dark spots or stains.

Additional features and aspects of the present disclosure will be set forth in the description that follows, and in part will be apparent from the description, or can be learned by practice of the disclosure provided herein. These and other features and aspects of the present disclosure can be realized and attained by the structure particularly pointed out in the written description, or derivable therefrom, and the claims hereof as well as the appended drawings.

To achieve these and other objects of the present disclosure, as embodied and broadly described herein, a display apparatus according to the present disclosure comprises a first substrate and a second substrate including a plurality of sub-pixels; a transistor disposed in a sub-pixel among the plurality of sub-pixels of the first substrate; a bank layer disposed between the plurality of sub-pixels; a light emitting device in the sub-pixel; an overcoat layer disposed in the second substrate; a filler disposed between the first substrate and the second substrate; and a groove formed in at least one of the overcoat layer and the bank layer in the sub-pixel.

The groove in the overcoat layer is overlapped with the bank layer.

A black matrix and a color filter layer are formed in the second substrate, and the groove formed in the overcoat layer is overlapped with the black matrix.

In another aspect of the present disclosure, a display apparatus comprises a first substrate and a second substrate including a plurality of pixels, each pixel having a display area for display desired images and a transparent area for transmitting light from behind; a transistor disposed in each of a plurality of sub-pixels disposed in a pixel among the plurality of pixels over the first substrate; a planarization layer over the display area and a part of the transparent area to cover the transistor; a bank layer disposed between the sub-pixels and outside the transparent area; a light emitting device in at least one of the sub-pixels; an overcoat layer over the second substrate; a filler between the first substrate and the second substrate; and a groove formed in the overcoat layer in the transparent area.

A signal line is disposed in the transparent area to apply a signal to the light emitting device, and a part of the planarization layer is removed in the transparent area so that the planarization layer may be disposed only over the signal line. Further, the planarization layer in the transparent area may be aligned with the groove in the overcoat layer.

A thickness of the planarization in the transparent area is smaller the thickness of the planarization in the display area.

A dam is formed along the edges of the first substrate and the second substrate to seal the filler.

### BRIEF DESCRIPTION OF THE DRAWINGS

The accompanying drawings, which are included to provide a further understanding of the present disclosure and are incorporated in and constitute a part of this application, illustrate aspects of the disclosure and together with the description serve to explain various principles of the present disclosure.

FIG. 1 is a schematic block diagram of an organic light emitting display apparatus according to an example embodiment of the present disclosure.

FIG. 2 is the schematic block diagram of an example sub-pixel of the organic light emitting display apparatus according to an example embodiment of the present disclosure.

FIG. 3 is a circuit diagram conceptually showing an example sub-pixel of the organic light emitting display apparatus according to an example embodiment of the present disclosure.

FIG. 4 is a plan view schematically showing the display apparatus according to an example embodiment of the present disclosure.

FIG. 5 is a cross-sectional view of the display apparatus according to a first example embodiment of the present disclosure.

FIG. 6 is a flowchart schematically showing a method for fabricating the display apparatus according to the first example embodiment of the present disclosure.

FIG. 7 is a cross-sectional view of the display apparatus according to a second example embodiment of the present disclosure.

FIGS. 8A and 8B are plan views schematically showing an example sub-pixel of the display apparatus according to a third example embodiment of the present specification.

FIG. 9 is a cross-sectional view of the display apparatus according to the third example embodiment of the present disclosure.

### DETAILED DESCRIPTION

Advantages and features of the present disclosure and methods for achieving them will be made clear from embodiments described in detail below with reference to the accompanying drawings. The present disclosure may, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains, and a protective scope of the present disclosure is defined by the scope of the appended claims and their equivalents.

Shapes, sizes, ratios, angles, numbers, and the like disclosed in the drawings for describing the embodiments of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein. When terms such as “including,” “having,” “comprising,” and the like mentioned in this disclosure are used, other parts may be added unless the term “only” is used herein. When a component is expressed as being singular, being plural is included unless otherwise specified.

In analyzing a component, an error range is interpreted as being included even when there is no explicit description.

In describing a positional relationship, for example, when a positional relationship of two parts is described as being “on,” “above,” “below,” “next to,” or the like, unless “immediately” or “directly” is used, one or more other parts may be located between the two parts.

In describing a temporal relationship, for example, when a temporal predecessor relationship is described as being “after,” “subsequent,” “next to,” “prior to,” or the like, unless “immediately” or “directly” is used, cases that are not continuous may also be included.

Although the terms first, second, and the like are used to describe various components, these components are not substantially limited by these terms. These terms are used only to distinguish one component from another component. Therefore, a first component described below may substantially be a second component within the technical spirit of the present disclosure.

In describing the components of the disclosure, terms such as first, second, A, B, (a), (b), etc. may be used. These terms are only for referring to the elements separately from other elements, and the essence, order, or number of the elements are not limited by the terms. When it is described that a component is “coupled” or “connected” to another component, the component may be directly coupled or connected to the other component, but indirectly without specifically stated. It should be understood that other components may be “interposed” between each component that is connected or can be connected.

As used herein, the term “apparatus” may include a display apparatus such as a liquid crystal module (LCM) including a display panel and a driving unit for driving the display panel, and an organic light emitting display module (OLED module). Further, the term “apparatus” may further include a notebook computer, a television, a computer monitor, a vehicle electric apparatus including an apparatus for a vehicle or other type of vehicle, and a set electronic apparatus or a set apparatus such as a mobile electronic apparatus of a smart phone or an electronic pad, etc., which are a finished product (complete product or final product) including LCM and OLED module.

Accordingly, the apparatus in the disclosure may include the display apparatus itself such as the LCM, the OLED module, etc., and the application product including the LCM, the OLED module, or the like, or the set apparatus, which is the apparatus for end users.

Hereinafter, the disclosure will be described in detail with reference to the accompanying drawings.

This disclosure can be applied to the various display apparatus. For example, the display apparatus of this disclosure can be applied to various display apparatus such as an organic light emitting display apparatus, a liquid crystal display apparatus, an electrophoretic display apparatus, a quantum dot display apparatus, a micro LED (Light Emitting Device) display apparatus, and a mini LED display apparatus. However, in the following description, the organic light emitting display apparatus will be described as an example for convenience of explanation.

Hereinafter, the present disclosure will be described in detail with reference to the attached drawings.

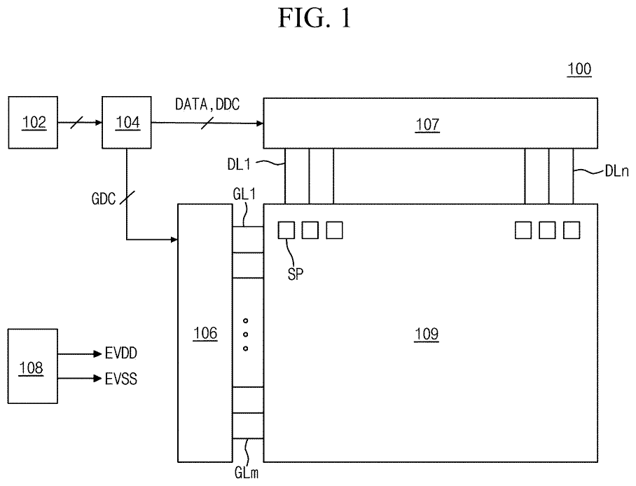

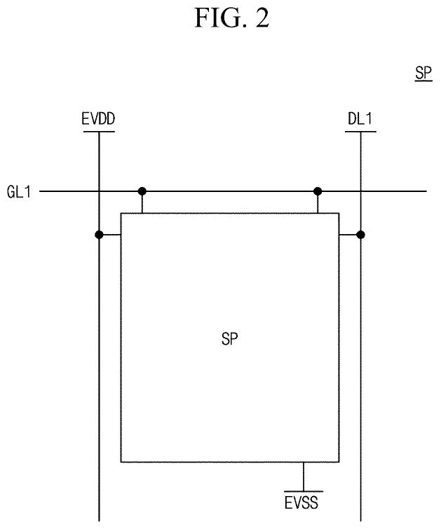

FIG. 1 is the schematic block diagram of a display apparatus 100 according to an example embodiment of the present disclosure, and FIG. 2 is the schematic block diagram of an example of the sub-pixel SP shown in FIG. 1.

As shown in FIG. 1, the organic light emitting display apparatus 100 includes an image processing unit 102, a timing controlling unit 104, a gate driving unit 106, a data driving unit 107, a power supplying unit 108, and a display panel 109.

The image processing unit 102 outputs an image data supplied from outside and a driving signal for driving various devices. For example, the driving signal from the image processing unit 102 can include a data enable signal, a vertical synchronizing signal, a horizontal synchronizing signal, and a clock signal.

The image data and the driving signal are supplied to the timing controlling unit 104 from the image processing unit 102. The timing controlling unit 104 writes and outputs gate timing controlling signal GDC for controlling the driving timing of the gate driving unit 106 and data timing controlling signal DDC for controlling the driving timing of the data driving unit 107 based on the driving signal from the image processing unit 102.

The gate driving unit 106 outputs the scan signal to the display panel 109 in response to the gate timing control signal GDC supplied from the timing controlling unit 104. The gate driving unit 106 outputs the scan signal through a plurality of gate lines GL1 to GLm. In this case, the gate driving unit 106 may be formed in the form of an integrated circuit (IC), but is not limited thereto. The gate driver 106 includes various gate driving circuits, and the gate driving circuits may be directly formed on the substrate 110. In this case, the gate driver 106 may be a gate-in-panel (GIP).

The data driving unit 107 outputs the data voltage to the display panel 109 in response to the data timing control signal DDC input from the timing controlling unit 104. The data driving unit 107 samples and latches the digital data signal DATA supplied from the timing controlling unit 104 to convert it into the analog data voltage based on the gamma voltage. The data driving unit 107 outputs the data voltage through the plurality of data lines DL1 to DLn. In this case, the data driving unit 107 may be mounted on the upper surface of the display panel 109 in the form of an integrated circuit (IC), but is limited thereto.

The power supplying unit 108 outputs a high potential voltage and a low potential voltage etc. to supply these voltages to the display panel 109. The high potential voltage is supplied to the display panel 109 through the first power line EVDD and the low potential voltage is supplied to the display panel 109 through the second power line EVSS. In this time, the voltage from the power supplying unit 108 are applied to the data driving unit 107 or the gate driving unit 106 to drive thereto.

The display panel 109 displays the image based on the data voltage from the data driving unit 108, the scan signal from the gage driving unit 106, and the power from the power supplying unit 108.

The display panel PAN includes a plurality of sub-pixels SP to display the image. The sub-pixel SP can include Red sub-pixel, Green sub-pixel, and Blue sub-pixel. Further, the sub-pixel SP can include White sub-pixel, the Red sub-pixel, the Green sub-pixel, and the Blue sub-pixel. The White sub-pixel, the Red sub-pixel, the Green sub-pixel, and the Blue sub-pixel may be formed in the same area or may be formed in different areas.

As shown in FIG. 2, one sub-pixel SP may be connected to the gate line GL1, the data line DL1, the first power line EVDD, and the second power line EVSS. The sub-pixel SP may include a plurality of thin film transistors and a storage capacitor depending on the configuration of the pixel circuit. For example, the sub-pixel SP may include two transistors and one capacitor (it is called 2T1C), but is not limited thereto. The sub-pixel SP may be composed of 3T1C, 4T1C, 5T1C, 6T1C, 7T1C, 3T2C, 4T2C, 5T2C, 6T2C, 7T2, 8T2C, etc.

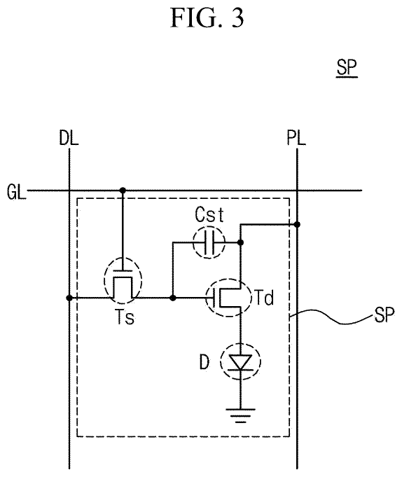

FIG. 3 is the circuit diagram illustrating the example sub-pixel SP of the organic light emitting display apparatus 100 according to an example embodiment of the present disclosure.

As shown in FIG. 3, the organic light emitting display apparatus 100 according to an example embodiment of the present disclosure includes the gate line GL, the data line DL, and the power line PL crossing each other for defining the sub-pixel SP. A switching thin film transistor Ts, a driving thin film transistor DT, a storage capacitor Cst, and a light emitting device D are disposed in the sub-pixel SP.

The switching thin film transistor Ts is connected to the gate line GL and the data line DL, and the driving thin film transistor Td and the storage capacitor Cst are connected between the switching thin film transistor Ts and the power line PL. The light emitting device D is connected to the driving thin film transistor Td.

In the organic light emitting display apparatus having this structure, when the switching thin film transistor Ts is turned on according to the gate signal applied to the gate line GL, the data signal applied to the data line DL is applied to the gate electrode of the driving thin film transistor Td and one electrode of the storage capacitor Cst through the switching thin film transistor Ts.

The driving thin film transistor Td is turned on according to the data signal applied to the gate electrode. As a result, the current proportional to the data signal is supplied to the light emitting device D from the power line PL through the driving thin film transistor Td and then the light emitting device D emits light with a luminance proportional to the current flowing through the driving thin film transistor Td.

At this time, the storage capacitor Cst is charged with the voltage proportional to the data signal to keep the voltage of the gate electrode of the driving thin film transistor Td constant for one frame.

In the figure, only two thin film transistors Td and Ts and one capacitor Cst are provided, but the present disclosure is not limited thereto. Three or more thin film transistors and two or more capacitors may be provided in the present disclosure.

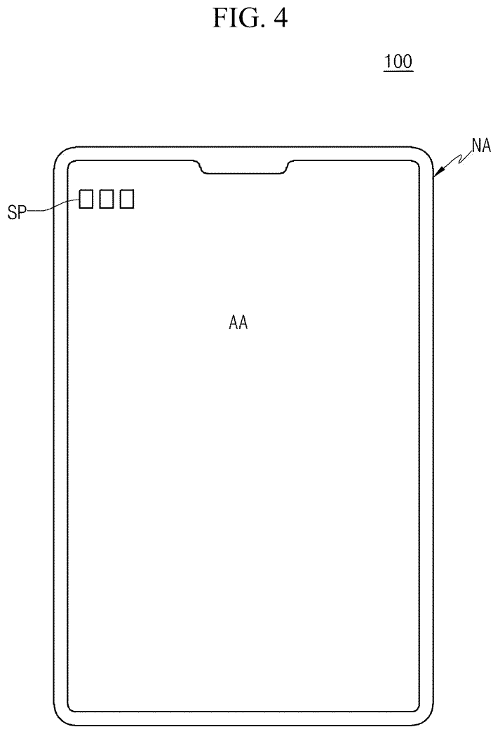

FIG. 4 is a plan view schematically showing the structure of the display apparatus 100 according to the present disclosure.

As shown in FIG. 4, the display apparatus 100 according to an example embodiment of the present disclosure includes an active area AA where the image is displayed and an outer area NA outside the display area AA.

A plurality of sub-pixels SP are disposed in the active area AA. The sub-pixel SP may include a red (R) sub-pixel, a green (G) sub-pixel, and a blue (B) sub-pixel. Further, the sub-pixel SP may further include a white (W) sub-pixel.

Although not shown in the drawing, a plurality of gate lines and data lines are arranged in the active area AA, and sub-pixels SP are arranged at the intersections of the gate lines and data lines. In each sub-pixel SP, a thin film transistor which is a switching element and a display apparatus for displaying the image are disposed.

The display apparatus may include various display devices. For example, the display device may be an organic light emitting display device, a liquid crystal display device, a quantum dot display device, a micro LED display device, or a mini LED display device.

The gate driving unit and the data driving unit for applying various signals to sub-pixels SP can be displaced in the outer area NA. The gate driving unit applies the scan signal to the sub-pixel SP through the gate line, and the data driving unit applies the image signal to the sub-pixel SP through the data line.

Further, various signal lines such as Vdd line that supplies a high potential voltage to the active region, Vss line that applies a low potential voltage, data link lines that apply the image signal to the data line, and gate link lines that apply the scan signal to the gate line are formed in the outer area NA.

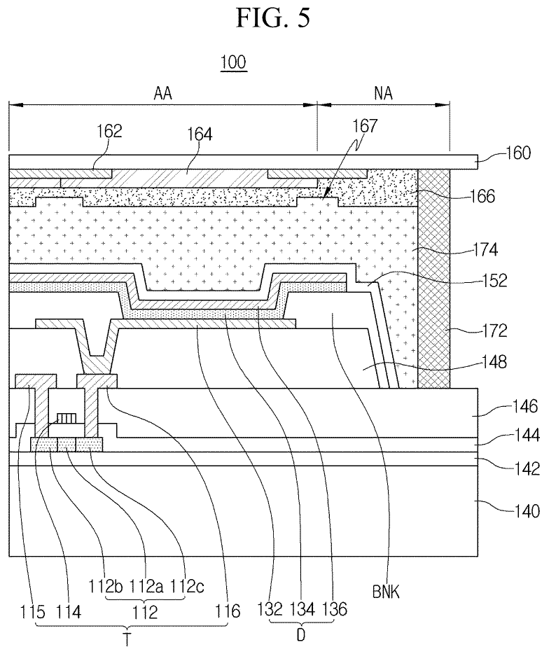

FIG. 5 is a cross-sectional view showing the structure of a sub-pixel of the display apparatus 100 according to a first example embodiment of the present disclosure. In the drawing, only two adjacent sub-pixels SP1 and SP2 disposed within the active region are shown for convenience of explanation. At this time, the sub-pixels SP1 and SP2 may include the red (R) sub-pixel, the green (G) sub-pixel, and the blue (B) sub-pixel, respectively. In addition, the sub-pixels SP1 and SP2 may further include the white (W) sub-pixel.

As shown in FIG. 5, the first substrate 140 including the active area AA and the outer area NA may be formed of a hard material such as glass or a flexible plastic material.

When the first substrate 140 is formed of the plastic material, the first substrate 140 may be made of at least one material of a polyimide, a polymethylmethacrylate, a polyethylene tereththalate, a Polyethersulfone, and a Polycarbonate, but not limited thereto.

When the first substrate 140 is made of polyimide, the substrate 140 may be made of a plurality of polyimide layers, and an inorganic layer may be further disposed between the polyimide layers, but is not limited thereto.

The buffer layer 142 may be formed on the active area AA and the outer area NA of the first substrate 140 to enhance adhering force between the first substrate 140 and the layers thereon. Further, the buffer layer 142 may block various types of defects, such as alkali components flowing out from the first substrate 140. In addition, the buffer layer 142 may delay diffusion of moisture or oxygen penetrating into the first substrate 140.

The buffer layer 142 may be a single layer made of silicon oxide (SiOx) or silicon nitride (SiNx), or multi-layers thereof. When the buffer layer 142 is made of multiple layers, SiOx and SiNx may be alternately formed. The buffer layer 142 may be omitted based on the type and material of the first substrate 140, the structure and type of the thin film transistor, and the like.

A thin film transistor T is formed in the active area on the buffer layer in each sub-pixel SP1, and SP2. For convenience of description, only the driving thin film transistor among various thin film transistors that may be disposed in the active area AA is illustrated, but other thin film transistors such as switching thin film transistors may also be included. In the figure, the thin film transistor of a top gate structure is shown, but the thin film transistor is not limited to this structure and may be formed in other structures such as the thin film transistor of a bottom gate structure.

The thin film transistor T includes a semiconductor pattern 112 disposed on the buffer layer 142, a gate insulating layer 144 covering the semiconductor pattern 112, a gate electrode 114 on the gate insulating layer 144, an interlayer insulating layer 146 covering the gate electrode 114, and a source electrode 115 and a drain electrode 116 on the interlayer insulating layer 146.

The semiconductor pattern 112 may be made of a polycrystalline semiconductor. For example, the polycrystalline semiconductor may be made of low temperature poly silicon (LTPS) having high mobility, but is not limited thereto.

The semiconductor pattern 112 may be made of an oxide semiconductor. For example, semiconductor pattern 112 may be made of one of IGZO (Indium-gallium-zinc-oxide), IZO (Indium-zinc-oxide), IGTO (Indium-gallium-tin-oxide), and IGO (Indium-gallium-oxide), but is not limited thereto. The semiconductor pattern 112 includes a channel region 112a in a central region and a source region 112b and a drain region 112c which are doped layers at both sides of the channel region 112a.

The gate insulating layer 144 may be formed in the active area AA and the outer area NA of the first substrate 140. The gate insulating layer 144 may be composed of a single layer or multiple layers made of an inorganic material such as SiOx or SiNx, but is not limited thereto.

The gate electrode 114 is made of a metal. For example, the gate electrode 114 may be formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto.

The interlayer insulating layer 146 is formed in the active area AA and the outer area NA. The interlayer insulating layer 146 may be made of the organic material such as photo-acryl, or the interlayer insulating layer 146 may formed of the single layer or the multiple layers made of the inorganic material such as SiOx or SiNx, but is not limited thereto. Further, the interlayer insulating layer 146 may be formed of the multi layers of the organic material layer and the inorganic material layer, but is not limited thereto.

The source electrode 115 and the drain electrode 116 are formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto. The source electrode 115 and the drain electrode 116 may be respectively contacted to the source region 112b and the drain region 112c of the semiconductor pattern 112 through contact holes formed in the gate insulating layer 144 and the interlayer insulating layer 146.

Although not shown in figure, a bottom shield metal layer may be disposed on the first substrate 140 under the semiconductor pattern 112. The bottom shield metal layer minimizes or reduces a backchannel phenomenon caused by charges trapped in the first substrate 140 to prevent or reduce afterimages or deterioration of transistor performance. The bottom shield metal layer may be composed of the single layer or the multi layers made of titanium (Ti), molybdenum (Mo), or an alloy thereof, but is not limited thereto.

A planarization layer 148 is formed on the substrate where the thin film transistor T is disposed. The planarization layer 148 may be formed of the organic material such as photoacrylic. But it is not limited thereto. The planarization layer 148 may include a plurality of layers including the inorganic layer and the organic layer.

In the drawing, the planarization layer 148 is formed only in the active area AA and not in the outer area NA, but the planarization layer 148 may also be formed in the outer area NA.

A light emitting device D is disposed in each sub-pixel SP1 and SP2 of the active area AA on the planarization layer 148. The light emitting device D includes a first electrode 132, a light emitting layer 134, and a second electrode 136.

The first electrode 132 may be an anode electrode. The first electrode 132 is disposed on the planarization layer 148 and electrically connected to the drain electrode 116 of the thin film transistor T through the contact hole formed in the planarization layer 148. The first electrode 132 may be formed of at least one of silver (Ag), aluminum (Al), gold (Au), molybdenum (Mo), tungsten (W), chromium (Cr), or an alloy thereof. Further, the first electrode 132 may be formed of a transparent metal oxide material such as indium tin oxide (ITO) or indium zinc oxide (IZO).

When the display apparatus 100 is a top emission type display apparatus, the first electrode 132 may further include an opaque conductive material layer to function as a reflective electrode that reflects light. When the display apparatus 110 is a bottom emission type display apparatus, the first electrode 132 may be made of the transparent conductive material such as ITO or IZO.

A bank layer BNK is formed at the boundary between the sub-pixels SP1 and SP2 on the planarization layer 148. The bank layer BNK may be a barrier wall to define sub-pixels SP1 and SP2. The bank layer BNK divides each sub-pixel to prevent light of a specific color output from adjacent sub-pixels from being mixed and output.

The bank layer BNK is made of at least one material of the inorganic insulating material such as SiNx or SiOx, the organic insulating material such as Benzo Cyclo Butene, acrylic resin, epoxy resin, phenolic resin, polyamide resin, or the photosensitizer including black pigment, but is not limited thereto.

The light emitting layer 134 can be formed on the upper surface of the first electrode 132, the inclined surfaces of the bank layer BNK, and at least a portion of the upper surface of the bank layer BNK. The light emitting layer 134 may be formed in the R, G, and B sub-pixels and may include an R-emitting layer that emits red light, a G-emitting layer that emits green light, and a B-emitting layer that emits blue light. Further, the light emitting layer 134 may include a W-emitting layer that emits white light.

The light emitting layer 134 may include an organic light emitting layer, an inorganic light emitting layer, a nano-sized material layer, a quantum dot, a micro LED light emitting layer, or a mini LED light emitting layer, but is not limited thereto.

When the light emitting layer 134 is the organic light emitting layer, the light emitting layer 134 is formed of a blue organic light emitting layer and a yellow fluorescent layer to emit the white light. Further, the light emitting layer 134 may be formed in a multi-stack structure. For example, when the light emitting layer 134 is formed in a triple stack structure, the first to third stacks may be arranged with two charge generation layers therebetween. Each of the first to third stacks may be formed of the organic light emitting layer, a hole injection layer, a hole transport layer, an electron transport layer, and an electron injection layer. For example, the organic light emitting layer of the first stack may emit red light, the organic light emitting layer of the second stack may emit blue light, and the organic light emitting layer of the third stack may emit green light.

The second electrode 136 is disposed on the light emitting layer 134. When the display apparatus 100 is the top emission type, the second electrode 136 may be made of the half-transparent conductive material that transmits light. For example, the second electrode 136 may be made of at least one or more of the alloys such as LiF/Al, CsF/Al, Mg:Ag, Ca/Ag, Ca:Ag, LiF/Mg:Ag, LiF/Ca/Ag, or LiF/Ca:Ag.

When the display apparatus 100 is the bottom emission type, the second electrode 136 may be the reflective electrode made of the opaque conductive material. For example, the second electrode 136 may be made of at least one or more of silver (Ag), aluminum (Al), gold (Au), molybdenum (Mo), tungsten (W), chromium (Cr), or alloys thereof.

An encapsulation layer 152 is formed over the light emitting device D in the active area AA. When the light emitting device D is exposed to impurities such as moisture or oxygen, a pixel shrinkage phenomenon in which the light emitting area is reduced or the defect such as a dark spot in the light emitting area may occur. Further, moisture or oxygen penetrating into the light emitting device D oxidizes the metal electrode. The encapsulation layer 154 blocks impurities such as the oxygen and the moisture from the outside to prevent or reduce defects of the light emitting device D and various electrodes.

The encapsulation layer 152 may be formed the single layer or may be formed of the multiple layers. When the encapsulation layer 152 is formed of the single layer, the encapsulation layer 152 may be formed of the inorganic material such as SiOx or SiNx, but is not limited thereto.

When the encapsulation layer 152 is formed of the multiple layers, the encapsulation layer 152 may be formed of a first inorganic encapsulation layer, an organic encapsulation layer, and a second inorganic encapsulation layer. The first and second inorganic encapsulation layers may be made of the inorganic material such as SiOx or SiNx, and the organic encapsulation layer may be made of the organic insulating material such as acrylic resin, epoxy resin, polyimide, polyethylene, or silicon oxycarbon (SiOC), but is not limited thereto.

A second substrate 160 is disposed over the encapsulation layer 152. As the first substrate 140, the second substrate 160 may be made of the hard material such as glass or a flexible plastic material. A black matrix 162 and a color filter layer 164 may be disposed on the second substrate 160.

The black matrix 162 is formed in a region where the image is not displayed, for example, the region between sub-pixels and the region where the thin film transistor is disposed, to prevent or reduce image quality degradation by blocking light from passing through this region. The black matrix 162 may be made of the metal or the metal oxide such as Cr or CrO, or may be made of a black resin.

The color filter layer 164 filters the light emitted from the light emitting device D to transmit only light of a desired color. The color filter layer 164 may include a red color filter layer that transmits red light, a green color filter layer that transmits green light, and a blue color filter layer that transmits blue light.

When the display apparatus 100 is the bottom emission type display apparatus, the color filter layer 164 may be disposed on the light emitting device D, for example, on the interlayer insulating layer 146 or on the gate insulating layer 144.

An overcoat layer 166 is formed on the black matrix 162 and the color filter layer 164. The overcoat layer 166 may be made of the inorganic layer or the organic layer, and may be formed of the multiple layers of inorganic layers and organic layers.

A plurality of grooves 167 are formed in overcoat layer 166. The grooves 167 may be arranged to overlap with the bank layer BNK and may also be arranged to overlap with the black matrix 162. In addition, the grooves 167 extend longitudinally and transversely along the area corresponding to the bank layer BNK. In the drawing, only one groove 167 is formed in the area corresponding to the bank layer BNK, but a plurality of grooves 167 may be formed in each area.

Further, the groove 167 may be contacted with the color filter layer 164 and/or the black matrix 162, unlike as shown in FIG. 5. That is, the groove 167 may concentrate the overcoat layer 166.

A dam 172 is disposed between the first substrate 140 and the second substrate 160. The dam 172 is disposed along the edges of the first substrate 140 and the second substrate 160 so as to bond the first substrate 140 and the second substrate 160 while maintaining a gap therebetween. The dam 172 may be made of the organic material such as the resin, but is not limited thereto.

A filler 174 is disposed in the region between the first substrate 140 and the second substrate 160 surrounded by the dam 172.

The filler 174 may be another adhesive layer that adheres the encapsulation layer 152 and the second substrate 160. At this time, the filler 174 may be made of a thermosetting adhesive resin, a photocuring adhesive resin, or a natural curing adhesive resin.

The filler 174 may be a blocking layer for blocking the moisture and the oxygen into the display apparatus 100. If there is no filling material in the space between the first substrate 140 and the second substrate 160, the moisture and the oxygen may penetrate from the outside into the display apparatus 100. Therefore, by filling the space between the first substrate 140 and the second substrate 160 with a moisture-proof layer that suppresses the penetration of moisture and oxygen, the moisture and the oxygen penetrating into the display apparatus 100 can be effectively blocked. At this time, the filler 174 may be made of a moisture-absorbing material or moisture-blocking material.

Further, the filler 174 may be made of the adhesive resin that adheres the encapsulation layer 152 and the second substrate 160 and the moisture-proof material that blocks moisture and oxygen.

The filler 174 can also maintain a constant gap between the first substrate 140 and the second substrate 160.

Since the filler 174 is confined inside the display apparatus 100 by the dam 172, the dam 172 acts as a sealant that seals the filler 174.

As described above, in the display apparatus 100 according to the present disclosure, the groove 166 is formed in the overcoat layer 167, for the following reasons.

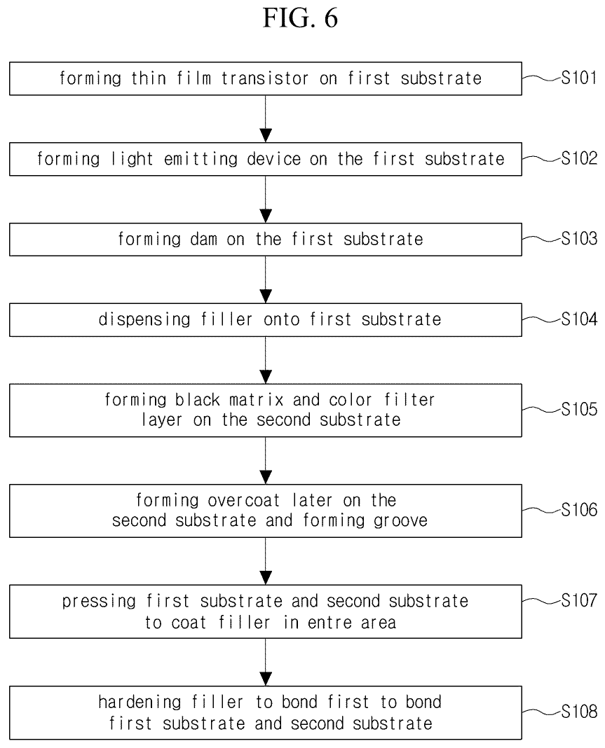

FIG. 6 is a flow chart briefly showing the fabricating process of the display apparatus 100 according to an example embodiment of the present disclosure.

First, as shown in FIG. 6, the first substrate 140 made of the hard material such as glass or the flexible plastic material is provided, and then the thin film transistor T including the semiconductor layer 112, the gate insulating layer 144, the gate electrode 113, the interlayer insulating layer 146, the source electrode 115, and the drain electrode 116 is formed in the active area AA of the first substrate 140 (S101).

Thereafter, the planarization layer 148 is formed over the thin film transistor T and the bank layer BNK having the matrix shape is formed between the sub-pixels, and then the light emitting device D including the first electrode 132, the light emitting layer 134, and the second electrode 136 is formed in each sub-pixel partitioned by the bank layer BNK (S102).

Subsequently, the dam 172 is formed along the edge of the first substrate 140 in the outermost region of the outer area NA of the first substrate 140 (S103).

Thereafter, the filler 174 is dispensed onto the first substrate 140 (S104). At this time, the dispensing area of the filler 174 can be formed in various areas depending on the structure or size of the display apparatus 100. In addition, the filler 174 can be dispensed onto the multiple dispensing areas.

Meanwhile, the black matrix 162 and the color filter layer 164 are formed over the second substrate 160 (S105), and then the overcoat layer 166 is formed thereon, and a portion of the overcoat layer 166 is etched to form the groove 167 in the region overlapped with the bank layer BNK (S106).

Subsequently, when the pressure is applied to the aligned first substrate 140 and second substrate 160, the filler 174 dispensed on the first substrate 140 spreads out by the pressure, and then the filler 174 is coated in the entire area of the first substrate 140 and second substrate 160 (S107).

Thereafter, the light is radiated, or heat is applied the filler 174 to harden the filler 174 (S108).

As described above, in the display apparatus 100 according to an example embodiment of the present disclosure, the filler 174 is used to bond the first substrate 140 and the second substrate 160. The filler 174 is dispensed onto the predetermined region and then the pressure is applied to the first substrate 140 and the second substrate 160 to coat the filler 174 in the entire area of the first substrate 140 and the second substrate 160.

Since the filler 174 is made of a fluid having viscosity, when pressure is applied to the first substrate 140 and the second substrate 160, the filler 174 is spread to the edge areas of the first substrate 140 and the second substrate 160. However, the filler 174 may not be uniformly spread over the entire area of the substrates 140 and 160 by the various conditions, for example, the physical properties of the filler 174, the external conditions such as adhesive strength, or the presence of foreign substances between the first substrate 140 and the second substrate 160. In particular, if the filler 174 is not smoothly spread, the filler 174 is not coated uniformly. For example, the thickness of the filler 174 in the corner area of the substrates 140 and 160 is thinner than in other areas.

If the filler 174 is not coated uniformly, the defects such as stains occur on the screen.

In example embodiments of the present disclosure, the groove 167 is formed in the overcoat layer 166 to prevent or reduce defects caused by non-uniform coating of the filler 174. Since the width of the groove 167 is about 30 μm or less, when the filler 174 is spread by the pressure, the groove 167 acts as a capillary to improve the spreadability of the filler 174. Therefore, regardless of the physical properties or bonding conditions of the filler 174, the filler 174 can be uniformly coated in the entire area of the substrates 140 and 160. In particular, since the filler 174 is uniformly coated in corners of the substrates 140 and 160, the defects caused by the non-uniform coating of the filler 174 can be prevented or reduced.

Since the groove 167 is formed in the area corresponding to the bank layer BNK, which is the area where the images are not displayed, the image defects due to the groove 167 do not occur.

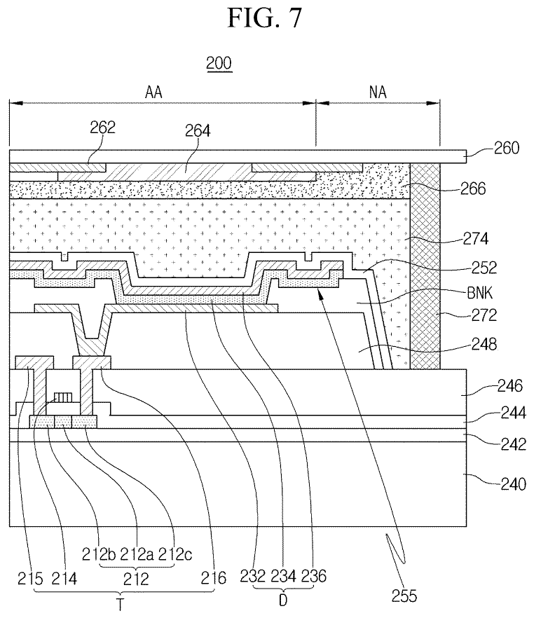

FIG. 7 is the cross-sectional view showing the structure of the display apparatus 200 according to the second embodiment of the present disclosure. At this time, the description of the same structure as the first embodiment of FIG. 5 will be omitted or simplified, and only the different structures will be described in detail.

As shown in FIG. 7, in the display apparatus 200 according to the second embodiment of the present disclosure, the thin film transistor T and the light emitting device D are disposed over the first substrate 240, and the encapsulation layer 252 is disposed thereon.

The thin film transistor T includes the semiconductor layer 212 disposed on the buffer layer 242, the gate electrode 214 disposed on the gate insulating layer 244, the source electrode 215 and the drain electrode 216 disposed on the interlayer insulating layer 246.

The light emitting device D includes the first electrode 232, the organic layer 234, the second electrode 236 which is a common electrode disposed in the entire sub-pixels.

The encapsulation layer 252 is formed over the entire area of the first substrate 240 to cover the second electrode 236.

The sub-pixels are partitioned by the bank layer BNK and the groove 255 is formed on the upper surface of the bank layer BNK. The width of the groove 255 may be about 30 μm or less, but is not limited thereto.

The light emitting layer 234 and the second electrode 236 may extend to the upper surface of the bank layer BNK, but are not limited thereto. When the light emitting layer 234 and the second electrode 236 are extended to the upper surface of the bank layer BNK, the light emitting layer 234, the second electrode 236, and the encapsulation layer 252 are also formed inside the groove 255, so that the groove is also formed in the upper surface of the light emitting layer 234, the second electrode 236, and the encapsulation layer 252.

The black matrix 262 and the color filter layer 264 are formed on the second substrate 260, and the filler 274 is coated between the first substrate 240 and the second substrate 260 so that the first substrate 240 and the second substrate 260 are bonded for each other. The dam 272 is formed at the edges of the first substrate 240 and the second substrate 260 to seal the filler 274.

In the display apparatus 200 of this embodiment, the groove 255 is formed in the bank layer BNK, and the capillary phenomenon occurs by the groove 255 when the filler 274 is coated. Accordingly, the spreadability of the fluid filler 274 is improved, so that the filler 274 is formed with a uniform thickness over the entire area of the display apparatus 200. As a result, the defects such as the dark spots and the stains caused by the non-uniform thickness of the filler 274 can be prevented or reduced.

Meanwhile, the groove 167 is formed in the overcoat layer 166 of the second substrate 160 to improve the spreadability of the filler 174 in the display apparatus 100 according to the first embodiment, and the groove 255 is formed in the bank layer BNK of the first substrate 240 to improve the spreadability of the filler 274 in the display apparatus 200 according to the second embodiment of the present disclosure. However, the groove may be formed in both the overcoat layer of the second substrate and the bank layer of the first substrate. In this case, the groove formed in the overcoat layer of the second substrate and the groove formed in the bank layer of the first substrate may be aligned at the same position, but is not limited thereto and may be formed at different positions.

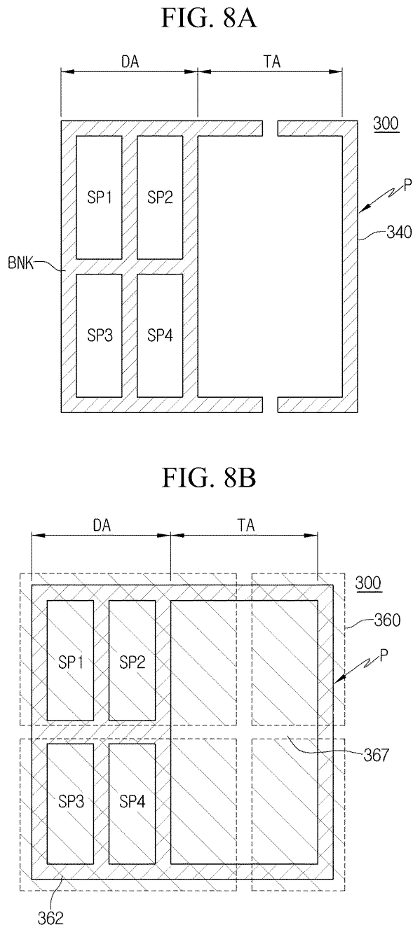

FIGS. 8A and 8B are plan views schematically showing the structure of an example pixel P of the display apparatus 300 according to a third example embodiment of the present disclosure. FIG. 8A is the plan view of the first substrate 340 on which a thin film transistor is formed, and FIG. 8B is the plan view of the second substrate 360 on which a color filter layer is formed. At this time, the display apparatus 300 according to the third embodiment is a transparent display apparatus. Therefore, in the display apparatus 300 of this embodiment, the desired image is displayed and the object behind the display apparatus 300 is also displayed.

As shown in FIGS. 8A and 8B, the pixel P includes the display area DA where the image is displayed and the transparent area TA where no image is displayed and external light is directly transmitted. A plurality of sub-pixels SP1, SP2, SP3, and SP4 are arranged in the display area DA.

For example, the first sub-pixel SP1 may be the red R sub-pixel, the second sub-pixel SP2 may be the G sub-pixel, the third sub-pixel SP3 may be the B sub-pixel, and the fourth sub-pixel SP4 may be the W sub-pixel. Further, only R, G, and B sub-pixels may be arranged in the display area DA.

The transparent area TA is the area through which the light from the rear of the display apparatus 300 is directly transmitted to display the background at the rear. Therefore, no sub-pixels are disposed in the transparent area TA. In other words, the thin film transistors and the light emitting device are not disposed in the transparent area TA.

The bank layer BNK is formed between the sub-pixels SP1, SP2, SP3, and SP4 of the display area DA and in the outside of the transparent area TA of the first substrate 340.

The black matrix 362 is formed between the sub-pixels SP1, SP2, SP3, and SP4 of the display area DA and in the outside of the transparent area TA of the second substrate 360. Further, although not shown in the drawing, the color filter layer of a corresponding color is formed on each of the sub-pixels SP1, SP2, SP3, and SP4 of the second substrate 360. At this time, the color filter layer may not be formed on the fourth sub-pixel SP4, i.e., the W sub-pixel that outputs white light, and the white light emitted from the light emitting device may be directly transmitted without filtering.

The groove 367 is formed in the second substrate 360. As described in the first and second embodiments, the groove 367 improves the flow of the filler so that the filler is uniformly coated in the entire area of the display apparatus 300. In the transparent display apparatus 300 according to this embodiment, the groove 367 is formed in the transparent area TA. Further, the groove 367 may also be formed between the sub-pixels SP1, SP2, SP3, and SP4 in the display area DA, and in this case the groove 367 may overlap with the black matrix 362.

As the groove 367 is formed in the transparent area TA, it is possible to prevent or reduce image quality degradation caused due to the changes in the optical path caused by the groove 367.

In the drawing, grooves 367 are formed in the horizontal and vertical directions in the transparent area TA, but this is not limited thereto. For example, a plurality of grooves 367 may be formed only in the horizontal direction and may formed only in the vertical direction. Further, the plurality of grooves 367 may be formed in the horizontal and vertical directions. The position and number of the grooves 367 may dependent upon the size of the display apparatus 300, the loading position of the filler, and the characteristics of the filler.

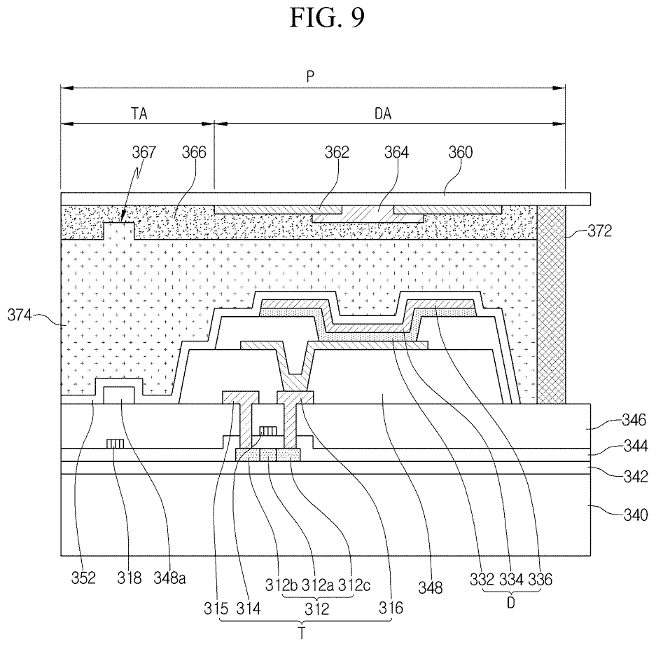

FIG. 9 is the cross-sectional view showing the structure of the display apparatus 200 according to the third example embodiment of the present disclosure. At this time, the description of the same structure as the first example embodiment of FIG. 5 will be omitted or simplified, and only the different structures will be described in detail.

As shown in FIG. 9, the display apparatus 300 of this example embodiment includes the display area DA for displaying the desired image and the transparent area TA for transmitting directly the rear light to display the rear object. In reality, a plurality of sub-pixels are arranged in the display area DA, but in the drawing only one sub-pixel is indicated for convenience of explanation.

The thin film transistor T and the light emitting device D are disposed in the display area DA over the first substrate 340.

The thin film transistor T includes the semiconductor layer 312 disposed on the buffer layer 342, the gate electrode 314 disposed on the gate insulating layer 344, the source electrode 315 and the drain electrode 316 disposed on the interlayer insulating layer 346.

The light emitting device D is disposed on the planarization layer 348. The light emitting device D includes the first electrode 332, the light emitting layer 334, and the second electrode 336 formed in the entire area of the display area DA. The bank layer BNK is formed between the sub-pixels of the display area DA and around the outer perimeter of the transparent area TA. The light emitting device D is disposed in each of the sub-pixels of the display area DA partitioned by the bank layer BNK. Further, the light emitting device D may be disposed in the entire area of the first substrate 340 including the display area DA and the transparent area TA.

The encapsulation layer 352 is formed over the entire area of the first substrate 340.

The black matrix 362 and the color filter layer 364 are formed over the second substrate 360, and the overcoat layer 366 is formed thereon. The filler 374 is coated between the first substrate 340 and the second substrate 360 so that the first substrate 340 and the second substrate 360 are bonded for each other. The dam 372 is formed at the edges of the first substrate 340 and the second substrate 360 to seal the filler 374.

The groove 367 is formed in the overcoat layer 366 in the transparent area TA.

Further, unlike as shown in FIG. 9, the groove 367 can be contacted with the second substrate 360. That is, the groove 367 can penetrate the overcoat layer 366.

Meanwhile, the signal line 318 is disposed in the transparent area TA. The signal line 318 may be the high potential voltage line for supplying the high potential voltage or the low potential voltage line for suppling the low potential voltage to the light emitting device D. The signal line 318 is disposed on the gate insulating layer 344 and may be formed of the same metal as the gate electrode 314 of the thin film transistor T through the same process, but is not limited thereto.

In the transparent area TA, the planarization layer 348 and the bank layer BNK are removed. This is to prevent light input from the rear of the display apparatus 300 from being absorbed by the planarization layer 348 and the bank layer BNK, thereby maximizing or increasing the transparency of the display apparatus 300. However, at least one of the planarization layer 348 and the bank layer BNK may be disposed on the signal line 318. The planarization layer 348a and the bank layer BNK on the signal line 318 can minimize or reduce interference between the signal line 318 and the metal line or the electrode thereon, thereby preventing or reducing signal delay.

However, in example embodiments of the present disclosure, the groove 367 formed in the overcoat layer 366 is overlapped with the signal line 318 and a part of the bank layer BNK and the planarization layer 348a on the signal line 318 are removed, so that the capillary phenomenon by the groove 367 is maximized or increased and thus the filler 374 flows very well.

Since the planarization layer 348a in the transparent area TA prevents or reduces the signal delay in the signal line 318 by the interference with other signal line and maximizes or increases the capillary phenomenon by the groove 367, it is preferable that the planarization layer 348a in the transparent area TA is formed in the minimum thickness that does not cause signal delay in the signal line 318.

For example, the thickness of the planarization layer 348a in the area corresponding to the groove 367 is about 50-90% of the thickness of the planarization layer 348 in the display area DA, but is not limited thereto.

As described above, the transparent display apparatus 300 of this embodiment includes the display area DA where the desired image is displayed by the pixel and the transparent area TA where the rear object is displayed, and the groove 367 for the flow of a filler 374 is formed in the overcoat layer 366 of the transparent area TA.

However, the transparent display apparatus 300 of the present disclosure is not limited to this structure. As shown in FIG. 5, the transparent display apparatus 300 according to an example embodiment of the present disclosure may have the groove 367 formed only in the overcoat layer 366 and/or the bank layer BNK of the display area DA rather than the transparent area TA. Further, the groove 367 may be formed not only in the overcoat layer 366 of the transparent area TA but also in the overcoat layer 366 and/or the bank layer BNK of the display area DA.

The above description and the accompanying drawings are merely illustrative of the technical spirit of the present disclosure, and those of ordinary skill in the art to which the present disclosure pertains can combine configurations within a range that does not depart from the essential characteristics of the present disclosure, various modifications or variations such as separation, substitution, and alteration will be possible. Therefore, the example embodiments disclosed in the present disclosure are not intended to limit the technical spirit of the present disclosure, but to explain, and the scope of the technical spirit of the present disclosure is not limited by these example embodiments.

What is claimed is:

1. A display apparatus, comprising:
a first substrate and a second substrate including a plurality of sub-pixels;
a transistor disposed in a sub-pixel among the plurality of sub-pixels of the first substrate;
a bank layer disposed between the plurality of sub-pixels;
a light emitting device in the sub-pixel;
an overcoat layer disposed in the second substrate;
a filler disposed between the first substrate and the second substrate; and
a groove formed in at least one of the overcoat layer and the bank layer in the sub-pixel.

2. The display apparatus of claim 1, wherein the groove in the overcoat layer is formed in a region where the bank layer is disposed.

3. The display apparatus of claim 1, further comprising:
a black matrix and a color filter layer in the second substrate.

4. The display apparatus of claim 1, wherein the groove formed in the overcoat layer is disposed a region where the black matrix is disposed.

5. The display apparatus of claim 1, wherein the groove causes a capillary phenomenon when the filler is collated.

6. The display apparatus of claim 1, further comprising a dam formed along the edges of the first substrate and the second substrate to seal the filler.

7. A display apparatus, comprising:
a first substrate and a second substrate including a plurality of pixels, each pixel having a display area for display desired images and a transparent area for transmitting light;
a transistor disposed in each of a plurality of sub-pixels disposed in a pixel among the plurality of pixels over the first substrate;
a planarization layer over the display area and a part of the transparent area to cover the transistor;
a bank layer disposed between the sub-pixels and outside the transparent area;
a light emitting device in at least one of the sub-pixels between;
an overcoat layer over the second substrate;
a filler between the first substrate and the second substrate; and
a groove formed in the overcoat layer in the transparent area.

8. The display apparatus of claim 7, further comprising:
a signal line disposed in the transparent area to apply a signal to the light emitting device.

9. The display apparatus of claim 7, wherein a part of the planarization layer is removed in the transparent area so that the planarization layer is disposed only over the signal line.

10. The display apparatus of claim 9, wherein the planarization layer in the transparent area is aligned with the groove in the overcoat layer.

11. The display apparatus of claim 10, wherein a thickness of the planarization in the transparent area is smaller the thickness of the planarization in the display area.

12. The display apparatus of claim 10, wherein the thickness of the planarization layer in the transparent area is in a range of 50-90% of the thickness of the planarization layer of the display area.

13. The display apparatus of claim 7, wherein the groove causes a capillary phenomenon when the filler is collated.

14. The display apparatus of claim 7, further comprising a dam formed along the edges of the first substrate and the second substrate to seal the filler.
